(19) United States
(12) Patent Application Publication
(10) Pub. No.: US 2017/0301874 A1
(43) Pub. Date: Oct. 19, 2017

(54) ORGANIC EL PANEL AND METHOD FOR PRODUCING SAME

(71) Applicant: NIPPON SEIKI CO., LTD., Niigata (JP)

(72) Inventors: Toyoyasu TADOKORO, Niigata (JP); Yotaro SHIRAISHI, Niigata (JP); Takashi IKEDA, Niigata (JP)

(21) Appl. No.: 15/513,549

(22) PCT Filed: Sep. 18, 2015
(86) PCT No.: PCT/JP2015/076752

§ 371 Date: Mar. 22, 2017

(30) Foreign Application Priority Data
Sep. 24, 2014 (JP) 2014-194283

(51) Int. Cl. H01L 51/50; H01L 51/52; H01L 51/00; H01L 51/56

(52) U.S. Cl. CPC H01L 51/5012; H01L 51/56; H01L 51/5253; H01L 51/0021; H01L 51/5209; H01L 51/5212

(57) ABSTRACT

Provided is a narrow-frame organic EL panel for suppressing unevenness in the brightness of light emission. The present invention involves positioning the following on a translucent support substrate: a translucent first electrode to which power is supplied from an external power source via common wiring, a second electrode for forming a pair with the first electrode, and an organic EL element in which an organic layer having at least a light-emitting layer is sandwiched between the first electrode and the second electrode. In addition, a sealing member is positioned so as to cover the organic EL element in an airtight manner, an auxiliary electrode having a lower specific resistance than that of the first electrode is formed on the first electrode, a groove is provided in at least a section of the sealing member, and an auxiliary conductive part comprising a conductive material is positioned in the groove.

### TECHNICAL FIELD

The present invention relates to an organic EL panel and a method for producing the same.

### BACKGROUND ART

It is necessary to suppress voltage drop in common wiring in order to cause an organic EL panel to uniformly emit light, and PTL 1 discloses an organic EL panel that places an auxiliary electrode having a lower electrical resistivity than that of a transparent electrode on common wiring of the transparent electrode to reduce an electrical resistivity of the transparent electrode and suppress voltage drop caused by the transparent electrode.

### CITATION LIST

### Patent Literature

PTL 1: JP-A-2003-123990

### SUMMARY OF INVENTION

### Technical Problem(s)

However, an organic EL panel serving as a light source is required to uniformly emit light at a high brightness, and therefore, in the case where the organic EL panel is formed to have a large area or a long length, an electric current flowing through common wiring is increased, and voltage drop in the common wiring is further increased. In order to suppress voltage drop in the common wiring, it is necessary to increase a wiring width of the common wiring, and therefore an area of the common wiring from an external power source placed in an outer region (frame) in a light-emitting unit of the organic EL panel is increased and the frame of the organic EL panel is increased. Thus, it is difficult to reduce a size of the organic EL panel.

The invention has been made in view of the above problems, and an object thereof is to provide a narrow-frame organic EL panel for suppressing unevenness in light emission luminance and a method for producing the same.

### Solution to Problem(s)

In order to achieve the above object, an organic EL panel according to a first aspect of the invention includes: a translucent first electrode to which power is supplied from an external power source via common wiring; a second electrode paired with the first electrode; an organic layer sandwiched between the first electrode and the second electrode, the organic layer having at least a light-emitting layer; a support substrate supporting the first electrode, the second electrode, and the organic layer; and a sealing member covering the first electrode, the second electrode, and the organic layer between the sealing member and the support substrate, wherein: an auxiliary electrode having a lower resistivity than a resistivity of the first electrode is provided on the first electrode; and a groove is provided in at least a part of the sealing member and an auxiliary conductive part is provided in the groove, the auxiliary conductive part being in contact with the auxiliary electrode and being made of a conductive material.

A method for producing an organic EL panel according to a second aspect is a method for producing an organic EL panel by dividing a common substrate into a plurality of organic EL panels, including: a step of forming a first electrode made of a translucent conductive material on a translucent support substrate and forming an auxiliary electrode having a lower resistivity than a resistivity of the conductive material on a part of the first electrode; a step of sequentially laminating an organic layer and a second electrode paired with the first electrode, the organic layer being a layer in which the auxiliary electrode is covered with an insulating material and having at least a light-emitting layer on the first electrode; a step of sealing the first electrode, the auxiliary electrode, the second electrode, and the organic layer with a sealing member on the support substrate; a division step of dividing the common substrate generated in the above step into a plurality of organic EL panels; and a step of forming an auxiliary conductive part made of a conductive material in a groove formed by the sealing member on an outer surface of the organic EL panel generated in the division step so that the auxiliary conductive part is brought into contact with the auxiliary electrode.

### Advantageous Effects of Invention

According to the invention, it is possible to provide a narrow-frame organic EL panel for suppressing unevenness in light emission luminance and a method for producing the same.

### BRIEF DESCRIPTION OF DRAWINGS

FIG. 1 is a planar view of a multi-organic EL substrate in an embodiment of the invention.

FIG. 2 is a cross-sectional view of the multi-organic EL substrate in the above embodiment, which is across-sectional view taken along A-A in FIG. 1.

FIG. 3 is cross-sectional views of the multi-organic EL substrate in the above embodiment, which is cross-sectional views taken along B-B in FIG. 1.

FIG. 4 is a cross-sectional view of the organic EL panel in the above embodiment, which is a cross-sectional view that does not cross an auxiliary electrode.

FIG. 5 is (a) a cross-sectional view and (b) a planar view of an organic EL panel in a modification example.

FIG. 6 is cross-sectional views of an organic EL panel in a modification example.

### DESCRIPTION OF EMBODIMENTS

Hereinafter, an embodiment of the invention will be described with reference to the attached drawings.

An organic EL panel 100 mainly includes a support substrate 10, a first electrode 20 formed on the support substrate 10, an auxiliary electrode 30 formed on a part of the first electrode 20, an insulating layer 40, an organic layer 50, a second electrode 60, a sealing member 70, an adhesive agent 80, and an auxiliary conductive part 90. The organic EL panel 100 includes first terminal parts 101 and second terminal parts 102, connects the first terminal parts 101 to an anode of an external power source (not shown) and connects the second terminal parts 102 to a cathode of the external power source, and causes a light-emitting unit E to emit light by supplying power to the first terminal parts 101 (second terminal parts 102). The organic EL panel 100 in this embodiment is formed by generating a plurality of organic EL panels 100 with the use of a common substrate (multi-organic EL substrate 100a) and then dividing the common substrate. In this way, the individual organic EL panels 100 are formed.

The support substrate 10 is made of a rectangular transparent glass material and is an electrically insulating substrate. Although a glass material is used for the support substrate 10 in this example, not only the glass material but also transparent materials such as plastics and ceramics can be used for the substrate.

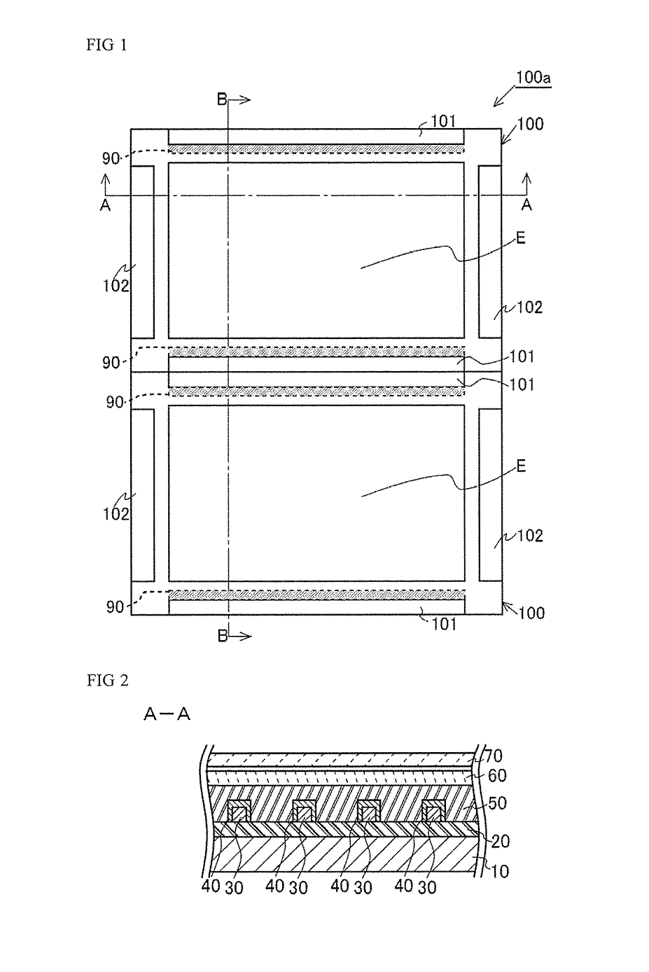

The first electrode 20 is made of a translucent conductive material such as ITO and is translucent wiring obtained by forming an electrode film on the support substrate 10 by means such as a vapor deposition method or a sputtering method and then patterning the electrode film to a predetermined shape by a photolithography method or the like. Although the first electrode 20 is formed on the whole light-emitting unit E in this embodiment, the first electrode 20 may be formed as a plurality of stripes vertical to left and right sides of the organic EL panel 100 in FIG. 1. The first electrode 20 has a common wiring structure in which the first electrode 20 is electrically connected to the external power source via the first terminal parts 101 described below and power is supplied to the whole first electrode 20 on the basis of supply of power from the external power source via the first terminal parts 101.

The auxiliary electrode 30 is non-translucent wiring obtained by forming a metal such as aluminum having a lower resistivity than that of the translucent conductive material of the first electrode 20 on the first electrode 20 by means such as the sputtering method so that the metal has a film of a single layer or laminated layers having a film thickness of 50 to 1500 nm and patterning the metal to a predetermined shape by means such as the photolithography method. In this embodiment, the auxiliary electrode 30 is formed on the first electrode 20 as a plurality of stripes vertical to the left and right sides of the organic EL panel 100 in FIG. 1.

The insulating layer 40 is made of, for example, a polymide-based transparent insulating material and is formed as layered thin films of about 1.0 μm by a spin coating method or the like and is then patterned to a desired shape by the photolithography method. The insulating layer 40 is formed between the auxiliary electrode 30 and the organic layer 50 described below so as to cover the auxiliary electrode 30 formed as a stripe on the first electrode 20, thereby preventing short circuit between the first electrode 20 and the second electrode 60 described below.

The organic layer 50 is formed on the first electrode 20, is formed by sequentially laminating a hole injection transport layer, a light-emitting layer, an electron transport layer, and an electron injection layer by means such as the vapor deposition method, and emits, for example, white light. Note that, in the organic layer 50, the light-emitting layer may be formed by a single layer or may be formed by adding another layer.

The second electrode 60 is formed as a layer by providing a metallic conductive material having a higher conductivity than that of the first electrode 20 such as aluminum or magnesium silver on a back surface side of the organic layer 50 by means such as the vapor deposition method. The second electrode 60 has a common wiring structure in which the second electrode 60 is electrically connected to the external power source via the second terminal parts 102 described below and power is supplied to the whole second electrode 60 on the basis of supply of power from the external power source via the second terminal parts 102.

The sealing member 70 is obtained by forming a plate member made of, for example, a glass material so that the plate member has a recessed shape by an appropriate method such as sandblasting, cutting, or etching and includes a plate part 71 facing to the organic layer 50, a support part 72 extending toward the support substrate 10 so as to surround the plate part 71, a division part 73 to be divided when the multi-organic EL substrate 100a is divided into the plurality of organic EL panels 100, and a groove 74 formed on the outside of the support part 72, the groove being formed by the plate part 71 and the support part 72. In this embodiment, the groove 74 is formed by any one of a thermal press molding method, an etching method, a sandblasting method, and a cutting method.

The adhesive agent 80 is made of, for example, ultraviolet-curable epoxy resin and is used to cause the support part 72 to adhere to the support substrate 10 (auxiliary electrodes 30), and therefore the organic layer 50 is provided on the support substrate 10 in an airtight manner, and the organic layer 50 is sealed by the sealing member 70 and the support substrate 10 (auxiliary electrodes 30). Further, the sealing member 70 is formed to be slightly smaller than the support substrate 10 so that end parts of the first electrode 20 and the second electrode 60 are exposed to the outside, and a part of the support part 72 is provided to be overlaid with the first electrode 20 and the second electrode 60.

The auxiliary conductive part 90 is made of, for example, a conductive paste having a volume resistivity of 1.5×10⁻⁴ Ω/cm and a viscosity of 10 Pa·s. After the multi-organic EL substrate 100a is divided, the auxiliary conductive part 90 is applied to the groove 74 formed by the plate part 71, the support part 72, and the auxiliary electrode 30 on side surfaces of each organic EL panel 100 so that the auxiliary conductive part 90 is electrically connected to the auxiliary electrode 30 and is then cured by heat.

The first terminal part 101 is a part of the first electrode 20 and the auxiliary electrode 30 formed on the support substrate 10, the part being extracted from the inside of the sealing member 70 to the outside thereof, and electrically connects the first electrode 20 and the auxiliary electrode 30 to the external power source.

The second terminal part 102 is formed by laminating a metal layer (not shown) made of a metal material having a low resistivity, such as chromium, on a base part (not shown) which is made of the same material as that of the first electrode 20 at the same time and electrically connects the second electrode 60 to the external power source.

The organic EL panel 100 is made up of the above parts. The organic EL panel 100 is a so-called bottom-emission type organic EL panel that emits light from the support-substrate-10 side.

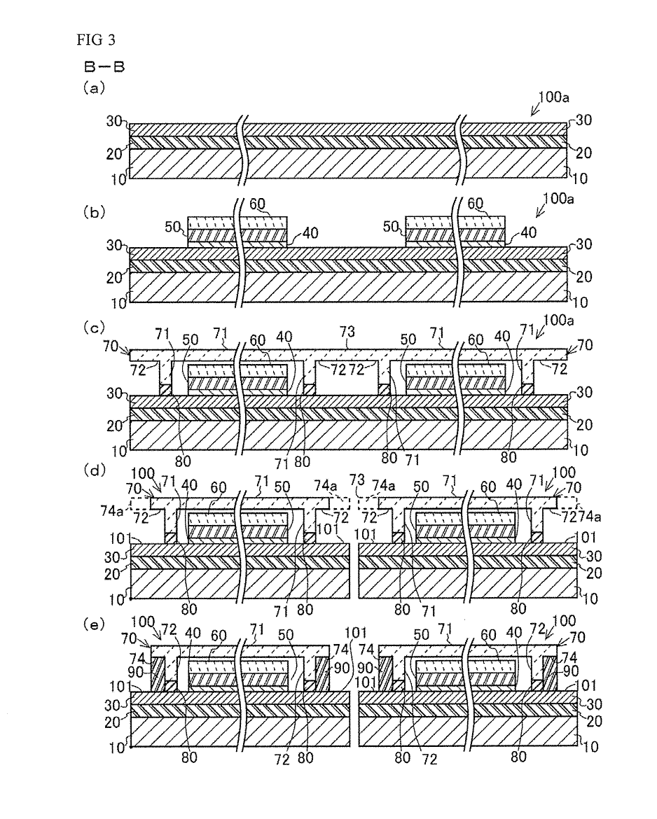

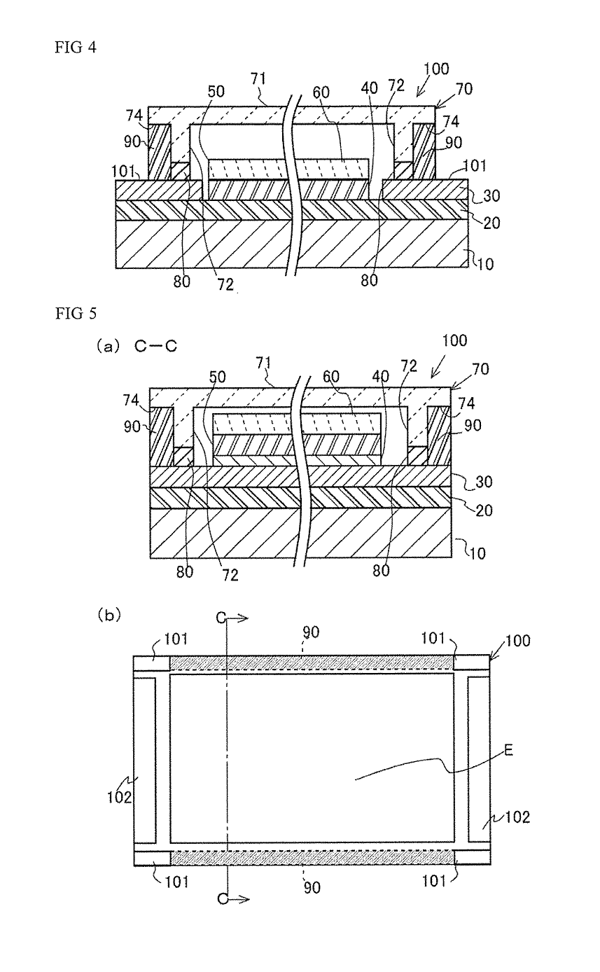

A method for producing the organic EL panel 100 will be described with reference to FIG. 3. FIG. 3 is cross-sectional views of the multi-organic EL substrate 100a, which is cross-sectional views taken along B-B in FIG. 1. Note that, although FIG. 3 is cross-sectional views passing through the auxiliary electrode 30, FIG. 4 is a cross-sectional view that does not pass through the auxiliary electrode 30, which is seen from the same direction.

First, in a “first electrode forming step, FIG. 3(a)”, the first electrode 20 and the auxiliary electrode 30 are formed on the support substrate 10 by means such as the vapor deposition method or the sputtering method, and then the slit-like first electrode 20 and auxiliary electrode 30 are formed on the support substrate 10 by the photolithography method or the like.

Next, the insulating layer 40 is formed to have a thin film shape on a back surface side of the auxiliary electrode 30 by the spin coating method or the like and is then patterned to a desired shape by the photolithography method. Then, in an “organic layer forming step and second electrode forming step, FIG. 3(b)”, the organic layer 50 is laminated to correspond to the first electrode 20, and the second electrode 60 is further laminated on the organic layer 50.

Next, in a “bonding step, FIG. 3(c)”, the sealing member 70 to which the adhesive agent 80 is applied and the support substrate 10 are overlaid in a nitrogen atmosphere while being kept in parallel by an overlaying device (not shown) so that each plate part 71 corresponds to the light-emitting unit E, and the support part 72 of the sealing member 70 and the support substrate 10 (auxiliary electrodes 30) are bonded and fixed by irradiation with ultraviolet rays, and thus the multi-organic EL substrate 100a including the plurality of organic EL panels 100 is obtained.

Next, in a “cutting step, FIG. 3(d)”, the division part 73, which is a boundary between the plurality of organic EL panels 100 in the multi-organic EL substrate 100a obtained in the bonding step, is cut by means such as a scribing method, and an excess part 74a, which is an excess portion of the groove 74, is cut by means such as the scribing method, and thus the individual organic EL panels 100 are obtained.

Then, in an “applying step, FIG. 3(e)”, the auxiliary conductive part 90 is applied to the groove 74 of the organic EL panel 100 with the use of a needle or the like, and after application, the auxiliary conductive part 90 is cured.

The organic EL panel 100 in this embodiment described above is obtained by providing, on the translucent support substrate 10, the translucent first electrode 20 to which power is supplied from an external power source via common wiring, the second electrode 60 paired with the first electrode 20, and an organic EL element in which the organic layer 50 having at least a light-emitting layer is sandwiched between the first electrode 20 and the second electrode 60 and providing the sealing member 70 covering the organic EL element in an airtight manner, and the auxiliary electrode 30 having a lower resistivity than that of the first electrode 20 is formed on the first electrode 20, the groove 74 is provided on at least a part of the sealing member 70, and the auxiliary conductive part 90 made of a conductive material is placed in the groove 74.

With this, an electrical resistivity against the first electrode 20 over the whole light-emitting unit E can be kept low even in the case where the width of the first terminal part 101 of the common wiring is not increased. That is, it is possible to cause the light-emitting unit E to uniformly emit light while keeping the electrical resistivity of the common wiring low, and therefore it is possible to provide the narrow-frame organic EL panel 100 having a narrow frame.

Note that the invention is not limited by the embodiment described above and the drawings. It is possible to make modifications (including elimination of constituent elements) as appropriate without changing the scope of the invention.

In the above embodiment, the organic EL element (organic layer 50), the support part 72 of the sealing member 70, the auxiliary conductive part 90, and the first terminal part 101 are placed in order from the center of the organic EL panel 100 to the outside thereof, and the first terminal part 101 is placed at an edge of the organic EL panel 100. However, as shown in FIG. 5(a), the auxiliary conductive parts 90 may be placed on the outside of the organic EL panel 100, and the first terminal parts 101 may be placed at both ends of the second terminal part 102 (vertical parts of the second terminal part 102 in FIG. 5(b)) so that electricity can be conducted to the auxiliary conductive parts 90. With this, it is unnecessary to provide a space for providing the first terminal part 101 on one opposite side of the organic EL panel 100, and therefore it is possible to provide the narrow-frame organic EL panel 100 having a narrow frame.

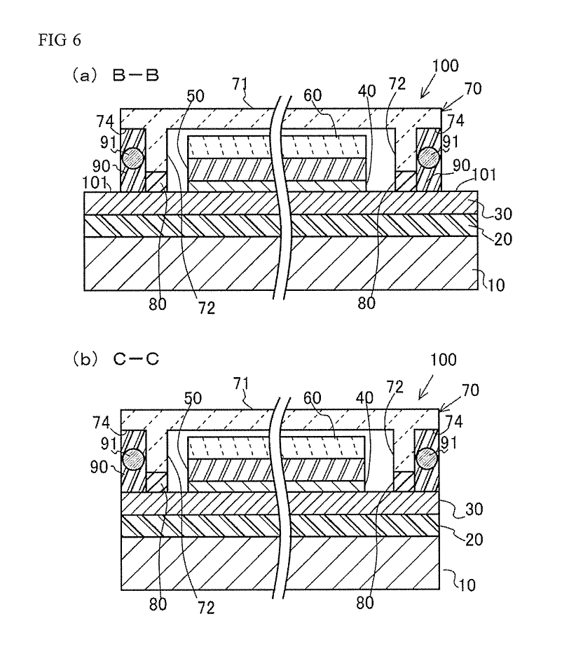

As shown in FIGS. 6(a) and 6(b), a conducting wire 91, which has a volume resistivity of 1.5×10⁻⁷ Ω/cm and is made of, for example, a tin coating copper wire having a diameter of 0.2 mm, may be provided in the auxiliary conductive part 90. With this structure, it is possible to keep the electrical resistivity of the common wiring (first electrode 20) lower and cause the light-emitting unit E to uniformly emit light, and therefore it is possible to provide the narrow-frame organic EL panel 100 having a narrow frame.

### INDUSTRIAL APPLICABILITY

The invention is suitable for an organic EL panel serving as a light source.

### REFERENCE SIGNS LIST

100 organic EL panel
100a multi-organic EL substrate
101 first terminal part
102 second terminal part
10 support substrate
20 first electrode
30 auxiliary electrode
40 insulating layer
50 organic layer
60 second electrode
70 sealing member
71 plate part
72 support part
73 division part
74 groove
80 adhesive agent
90 auxiliary conductive part
91 conducting wire
E light-emitting unit

1. An organic EL panel, comprising:
a translucent first electrode to which power is supplied from an external power source via common wiring;
a second electrode paired with the first electrode;
an organic layer sandwiched between the first electrode and the second electrode, the organic layer having at least a light-emitting layer;
a support substrate supporting the first electrode, the second electrode, and the organic layer; and
a sealing member covering the first electrode, the second electrode, and the organic layer between the sealing member and the support substrate, wherein:
an auxiliary electrode having a lower resistivity than a resistivity of the first electrode is provided on the first electrode; and
a groove is provided in at least a part of the sealing member and an auxiliary conductive part is provided in the groove, the auxiliary conductive part being in contact with the auxiliary electrode and being made of a conductive material.

2. The organic EL panel according to claim 1, wherein
the groove is provided on an outer surface of the sealing member.

3. The organic EL panel according to claim 1, wherein
the sealing member includes a plate part facing to the organic layer and a support part extending toward the support substrate so as to surround the plate part, a part of the plate part extends from the support part to the outside, and the groove is formed by the support part and the plate part extending from the support part to the outside.

4. The organic EL panel according to claim 1, wherein
the auxiliary conductive part is made of a conductive paste.

5. The organic EL panel according to claim 1, wherein
the auxiliary conductive part includes a conducting wire electrically connected to the auxiliary electrode.

6. A method for producing an organic EL panel by dividing a common substrate into a plurality of organic EL panels, comprising:
a step of forming a first electrode made of a translucent conductive material on a translucent support substrate and forming an auxiliary electrode having a lower resistivity than a resistivity of the conductive material on a part of the first electrode;
a step of sequentially laminating an organic layer and a second electrode paired with the first electrode, the organic layer being a layer in which the auxiliary electrode is covered with an insulating material and having at least a light-emitting layer on the first electrode;
a step of sealing the first electrode, the auxiliary electrode, the second electrode, and the organic layer with a sealing member on the support substrate;
a division step of dividing the common substrate generated in the above step into a plurality of organic EL panels; and
a step of forming an auxiliary conductive part made of a conductive material in a groove formed by the sealing member on an outer surface of the organic EL panel generated in the division step so that the auxiliary conductive part is brought into contact with the auxiliary electrode.
